(19) United States
(12) Patent Application Publication
(10) Pub. No.: US 2022/0385036 A1
(43) Pub. Date: Dec. 1, 2022

(54) LASER WITH WAVELENGTH-SELECTIVE REFLECTOR

(71) Applicant: ROCKLEY PHOTONICS LIMITED, Altrincham (GB)

(72) Inventors: Jin-Hyoung LEE, Brea, CA (US); Yi ZHANG, Pasadena, CA (US)

(21) Appl. No.: 17/829,030

(22) Filed: May 31, 2022

Related U.S. Application Data
(60) Provisional application No. 63/195,636, filed on Jun. 1, 2021.

(30) Foreign Application Priority Data
Oct. 7, 2021 (GB) 2114376.3

(51) Int. Cl. H01S 5/14

(52) U.S. Cl. CPC H01S 5/142

(57) ABSTRACT

A laser. In some embodiments, the laser includes an optical amplifier, and an output reflector. The output reflector may be configured to receive light from the optical amplifier and to reflect light at a first wavelength back toward the optical amplifier. The output reflector may include a wavelength-selective element, and a coupler configured to receive the light from the optical amplifier and to couple a portion of the light to the wavelength-selective element.

### CROSS-REFERENCE TO RELATED APPLICATION(S)

The present application (i) claims priority to and the benefit of U.S. Provisional Application No. 63/195,636, filed Jun. 1, 2021, entitled “A CHIP-SCALE EXTERNAL-CAVITY LASER BASED ON ECHELLE GRATING REFLECTOR”, and (ii) claims priority to United Kingdom Patent Application No. 2114376.3, filed in the United Kingdom Intellectual Property Office on Oct. 7, 2021, entitled “LASER WITH WAVELENGTH-SELECTIVE REFLECTOR”, which claims priority to and the benefit of U.S. Provisional Application No. 63/195,636, filed Jun. 1, 2021, entitled “A CHIP-SCALE EXTERNAL-CAVITY LASER BASED ON ECHELLE GRATING REFLECTOR”; the entire contents of all of the documents identified in this paragraph are incorporated herein by reference.

### FIELD

One or more aspects of embodiments according to the present disclosure relate to lasers, and more particularly to a laser having a wavelength-selective reflector.

### BACKGROUND

External-cavity lasers may be used to create a narrow laser linewidth with precise wavelength control. This type of laser may be built with multiple free space optical components which may result in a laser having a large footprint. An external-cavity laser may also be fabricated on a chip, e.g., on a silicon photonics chip. One of the key components of an external-cavity laser may be a wavelength-selective filter, which may be constructed to have high precision wavelength registration and a very narrow bandwidth. For example, a distributed Bragg reflector (DBR) or ring resonator-based filter may be employed as the wavelength-selective filter. However, such components may be challenging to fabricate because they may include small features, e.g., gratings with feature sizes comparable to the wavelength.

Thus, there is a need for an improved external cavity laser.

### SUMMARY

According to an embodiment of the present disclosure, there is provided a laser, including: an optical amplifier; and an output reflector, the output reflector being configured to receive light from the optical amplifier and to reflect light at a first wavelength back toward the optical amplifier, the output reflector including: a wavelength-selective element, and a coupler configured to receive the light from the optical amplifier and to couple a portion of the light to the wavelength-selective element.

In some embodiments, the wavelength-selective element includes an arrayed waveguide grating.

In some embodiments, the arrayed waveguide grating has a free spectral range greater than 50 nm.

In some embodiments, the wavelength-selective element includes an echelle grating.

In some embodiments, the echelle grating occupies less than 4 mm².

In some embodiments, the echelle grating has a 3 dB bandwidth of less than 0.6 nm.

In some embodiments: the wavelength-selective element has a first port, the optical amplifier is connected to a first port of the coupler, the first port of the coupler being at a first end of the coupler, a third port of the coupler is connected to the first port of the wavelength-selective element, the third port of the coupler being at a second end of the coupler.

In some embodiments, the wavelength-selective element is a Littrow echelle grating.

In some embodiments, the wavelength-selective element further has a second port.

In some embodiments, the second port of the wavelength-selective element is connected to a fourth port of the coupler, the fourth port of the coupler being at the second end of the coupler.

In some embodiments, the wavelength-selective element is a composite wavelength-selective element including: a first wavelength-selective element, and a second wavelength-selective element.

In some embodiments, the first wavelength-selective element is an arrayed waveguide grating.

In some embodiments, the first wavelength-selective element is an echelle grating.

In some embodiments, the second wavelength-selective element is a ring resonator.

In some embodiments, the laser further includes a tuning circuit configured to control a resonant wavelength of the ring resonator.

In some embodiments, the coupler includes a directional coupler.

In some embodiments, the coupler includes a Y-coupler.

In some embodiments, the coupler is connected to the wavelength-selective element by a waveguide having a core including at least 70 atomic percent silicon.

In some embodiments, the coupler is connected to the wavelength-selective element by a waveguide having a core including at least 35 atomic percent silicon and at least 35 atomic percent nitrogen.

In some embodiments, the laser is capable of operating at a wavelength of less than 1 micron.

In some embodiments, the laser is configured to produce light at a first wavelength, the first wavelength being within 0.2 nm of a standard-specified wavelength.

According to an embodiment of the present disclosure, there is provided a method, including: fabricating 100 operating lasers, in order, wherein each of the 100 operating lasers produces, in operation, light of a respective operating wavelength, of 100 respective operating wavelengths, the 100 operating wavelengths having a sample standard deviation of less than 0.2 nm.

### BRIEF DESCRIPTION OF THE DRAWINGS

These and other features and advantages of the present disclosure will be appreciated and understood with reference to the specification, claims, and appended drawings wherein:

FIG. 1A is a schematic drawing of a laser, according to an embodiment of the present disclosure;

FIG. 1B is a graph of a transmission function, according to an embodiment of the present disclosure;

FIG. 1C is a table of design parameters, according to an embodiment of the present disclosure;

FIG. 1D is a schematic drawing of a laser, according to an embodiment of the present disclosure;

FIG. 2A is a schematic drawing of a laser, according to an embodiment of the present disclosure;

FIG. 2B is a graph of a transmission function, according to an embodiment of the present disclosure;

FIG. 2C is a graph of a transmission function, according to an embodiment of the present disclosure;

FIG. 3A is a schematic cross-sectional drawing of waveguide, according to an embodiment of the present disclosure;

FIG. 3B is a table of design parameters, according to an embodiment of the present disclosure;

FIG. 3C is a graph of a transmission function, according to an embodiment of the present disclosure;

FIG. 3D is a graph of a transmission function, according to an embodiment of the present disclosure;

FIG. 4A is a schematic drawing of a laser, according to an embodiment of the present disclosure;

FIG. 4B is a schematic drawing of a laser, according to an embodiment of the present disclosure;

FIG. 4C is a table of design parameters, according to an embodiment of the present disclosure;

FIG. 4D is a graph of a transmission function, according to an embodiment of the present disclosure;

FIG. 4E is a graph of a transmission function, according to an embodiment of the present disclosure;

FIG. 4F is a graph of a transmission function, according to an embodiment of the present disclosure;

FIG. 4G is a table of design parameters, according to an embodiment of the present disclosure;

FIG. 4H is a graph of a transmission function, according to an embodiment of the present disclosure;

FIG. 4I is a graph of a transmission function, according to an embodiment of the present disclosure;

FIG. 4J is a graph of a transmission function, according to an embodiment of the present disclosure;

FIG. 4K is a table of design parameter values and corresponding bandwidths, according to an embodiment of the present disclosure;

FIG. 4L is a layout drawing of a portion of an arrayed waveguide grating, according to an embodiment of the present disclosure;

FIG. 4M is an enlarged view of a portion of FIG. 4L;

FIG. 4N is a graph of transmission as function of taper length, according to an embodiment of the present disclosure;

FIG. 4O is a table of design parameters, according to an embodiment of the present disclosure;

FIG. 4P is a graph of a transmission function, according to an embodiment of the present disclosure;

FIG. 4Q is a graph of a transmission function, according to an embodiment of the present disclosure;

FIG. 4R is a table of design parameters, according to an embodiment of the present disclosure;

FIG. 4S is a graph of a transmission function, according to an embodiment of the present disclosure; and

FIG. 4T is a graph of a transmission function, according to an embodiment of the present disclosure.

### DETAILED DESCRIPTION

The detailed description set forth below in connection with the appended drawings is intended as a description of exemplary embodiments of a laser with wavelength-selective reflector provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

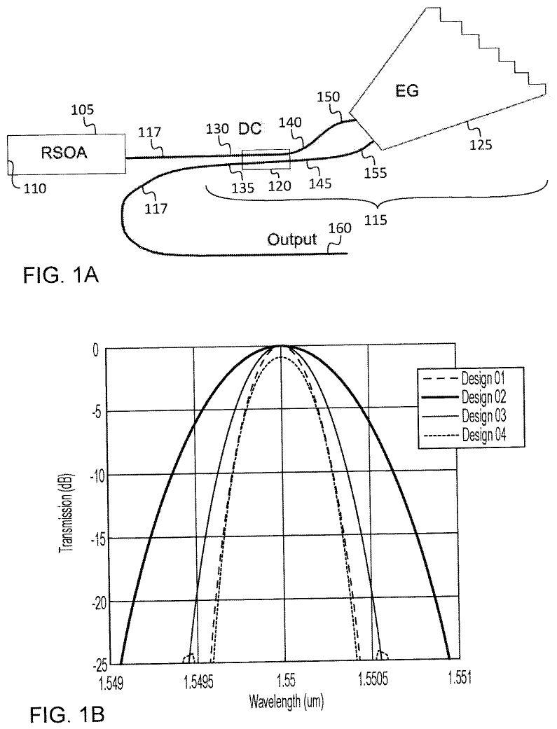

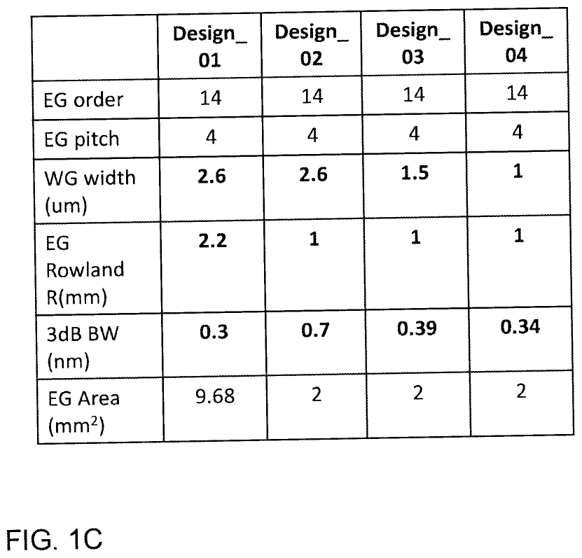

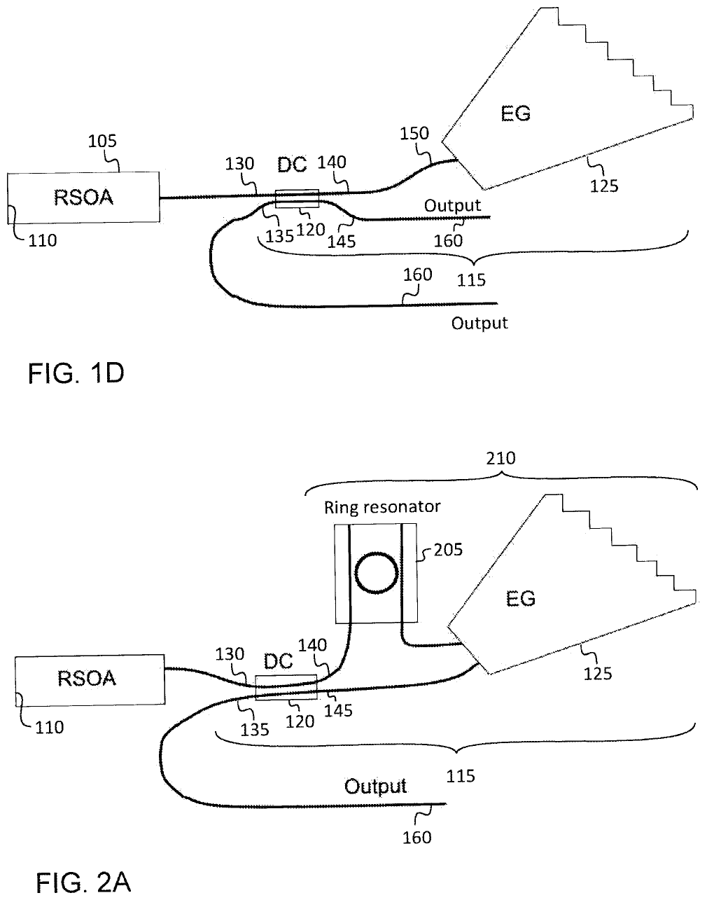

In some embodiments, an external cavity laser is constructed as illustrated in FIG. 1A. The laser includes a semiconductor optical amplifier 105 (SOA) (e.g., a reflective semiconductor optical amplifier (RSOA)), a first reflector, which may be referred to as an “end reflector” 110, and a second reflector which may be referred to as an output reflector 115. The two reflectors may form an optical cavity for the laser, or a “laser resonator”. In operation the semiconductor optical amplifier may be a source of optical power that is then coupled to the output of the laser through the output reflector 115.

The end mirror may be part of (e.g., formed on one facet of) the semiconductor optical amplifier (e.g., if the semiconductor optical amplifier is a reflective semiconductor optical amplifier). The opposite end facet of the semiconductor optical amplifier may have an antireflection (AR) coating. In some embodiments, the end reflector 110 is a separate element from the semiconductor optical amplifier. In some embodiments, the optical output from the laser consists of light exiting the laser cavity through the output reflector 115; in other embodiments, the optical output from the laser may instead, or also, include light transmitted through the end reflector 110 (which may be partially transmissive). As such, although the terms “end reflector” and “output reflector” are used herein to describe, in some embodiments, a highly reflective reflector and a partially transmissive reflector, respectively, the meanings of these terms are not limited to such reflectors. As shown in FIG. 1A, waveguides 117 (e.g., optical waveguides, on a silicon photonics chip) may be employed to connect the components to each other and may guide light between the components.

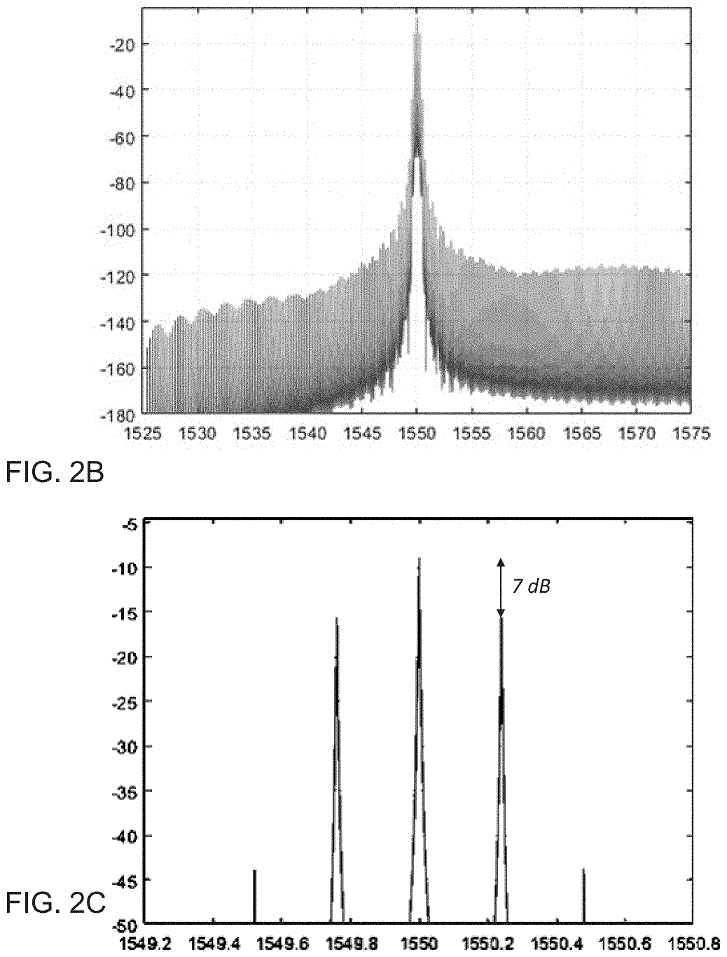

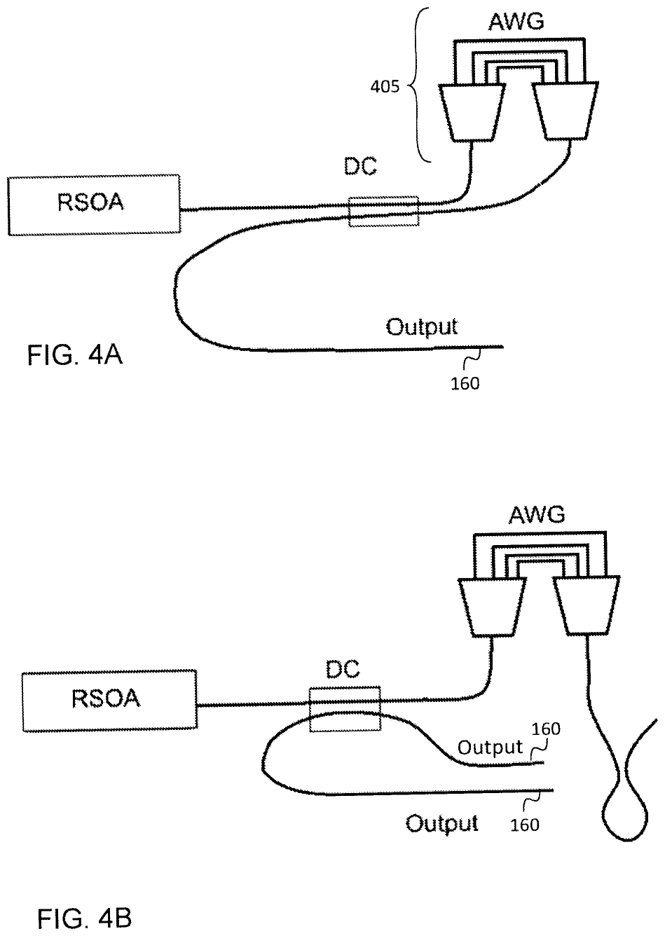

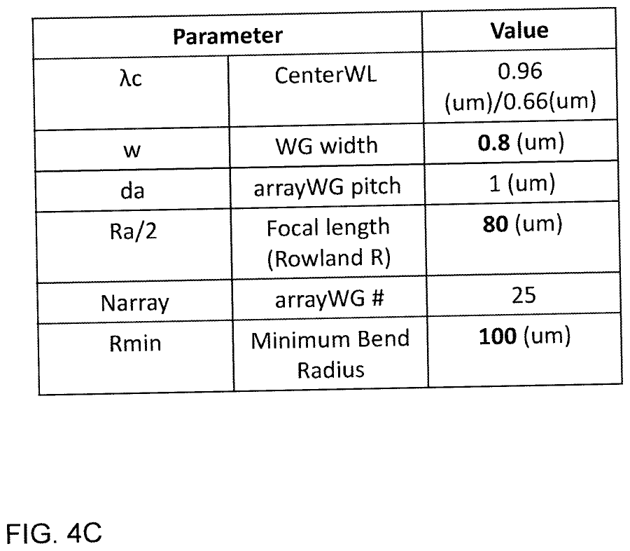

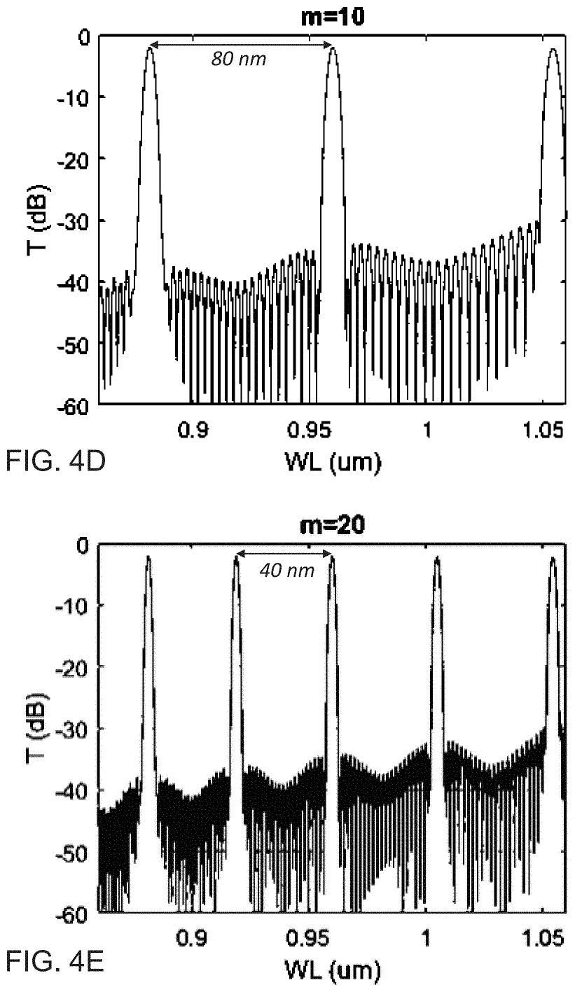

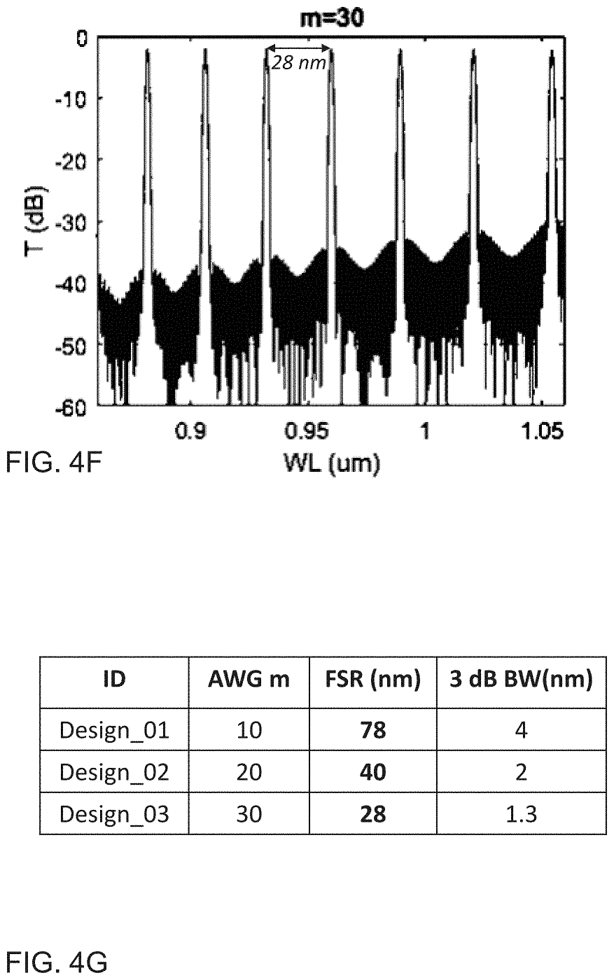

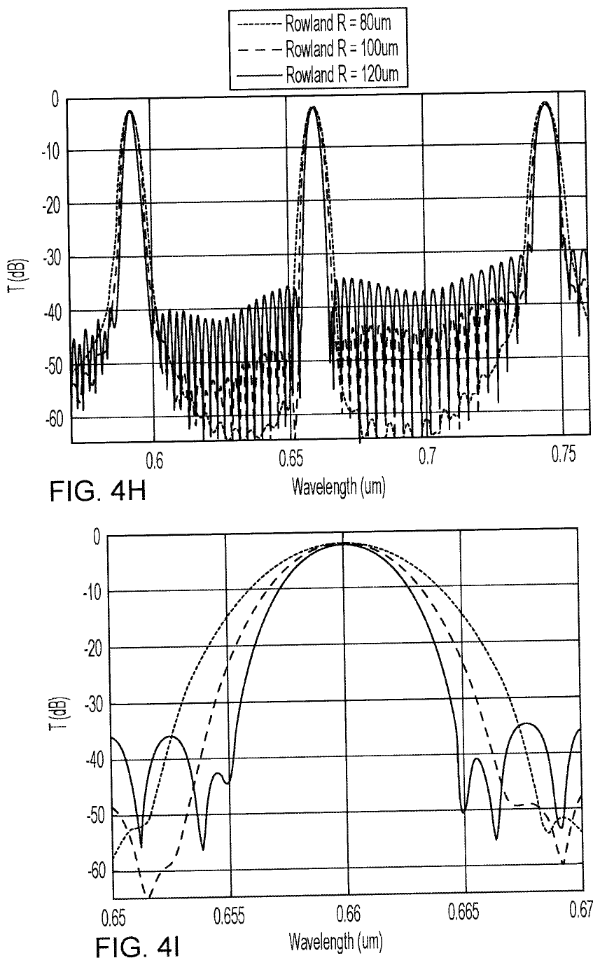

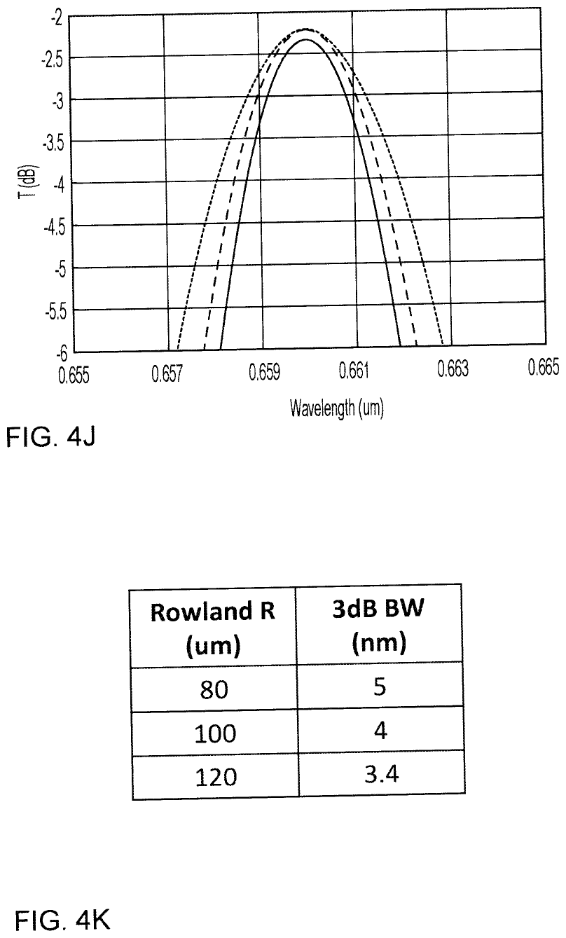

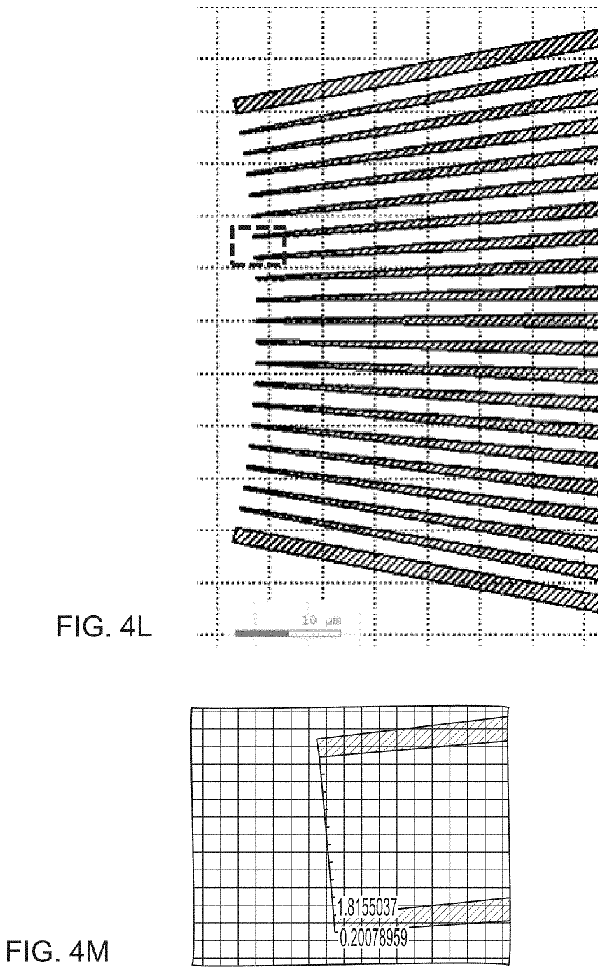

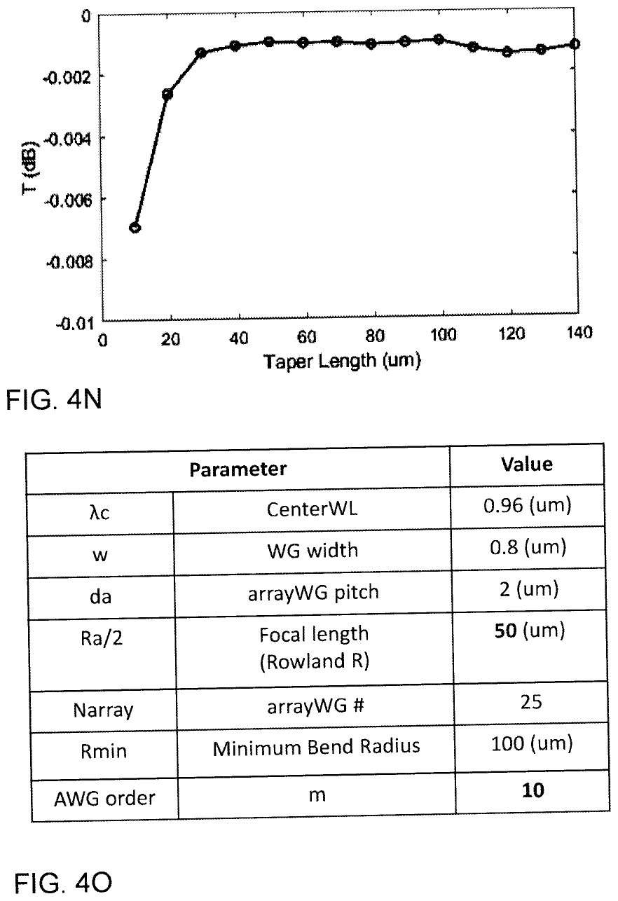

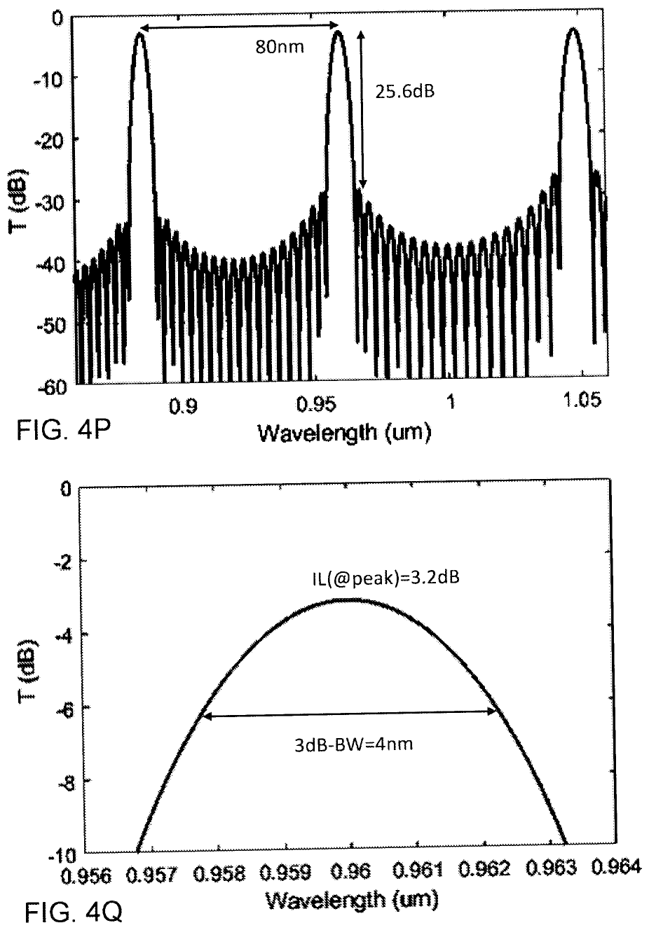

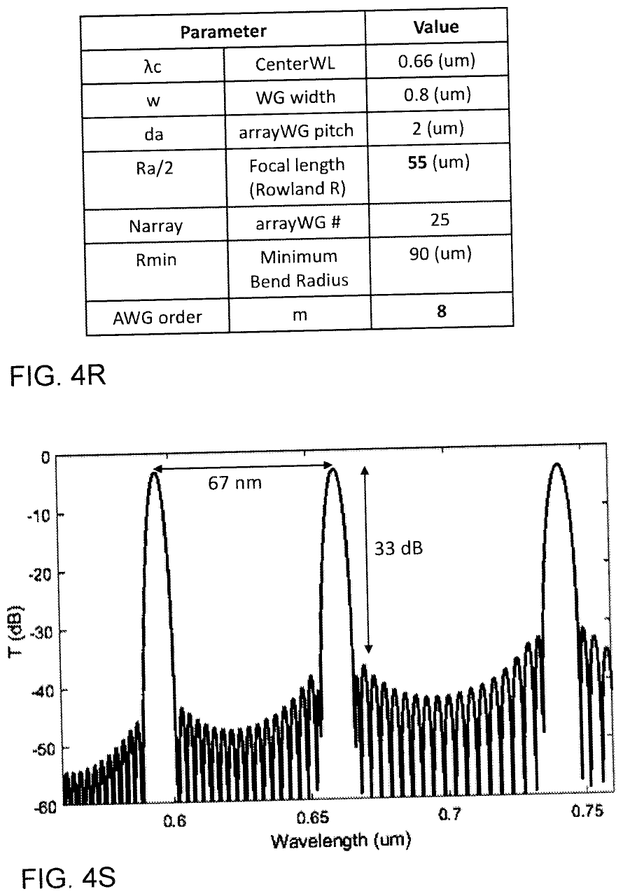

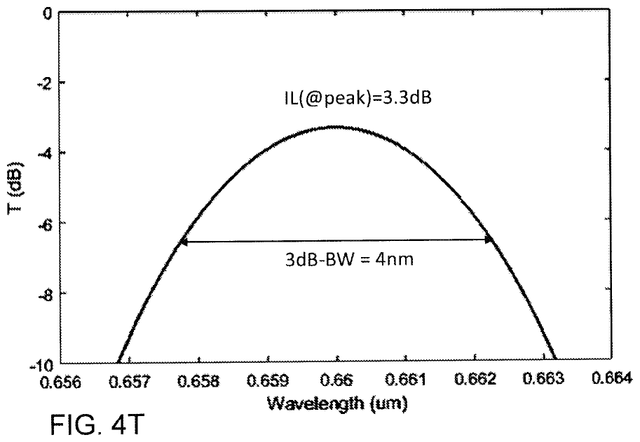

The output reflector 115 may, as illustrated in FIG. 1A, include a coupler (e.g., a directional coupler 120), and a wavelength-selective element, e.g., an echelle grating 125. The echelle grating 125 may be referred to as a “two-port” or “transmissive” wavelength-selective element, which transmits light within a narrow range of wavelengths (or, more precisely, within each of a plurality of narrow transmission peaks separated from each other by the free spectra range (FSR) of the echelle grating 125). When such a wavelength-selective element (which need not be an echelle grating 125, as illustrated for example by the embodiments of FIGS. 2A and 4A, discussed in further detail below) is connected in a waveguide loop at the second end of the directional coupler 120, the combination of the directional coupler 120 and the wavelength-selective element may operate as a reflective wavelength-selective element, which reflects a portion of the light received at the first port 130 of the directional coupler 120 (discussed in further detail below). This reflective wavelength-selective element may constrain the laser to operate in a single longitudinal mode of the laser cavity, as explained in further detail below.

The directional coupler 120 may include (i) the first port 130 (which may be referred to as an input port) and a second port 135 (which may be referred to as an isolated port) at a first end of the directional coupler 120, and (ii) a third port 140 (which may be referred to as the output port) and a fourth port 145 (which may be referred to as the coupled port) at a second end of the directional coupler 120. The echelle grating 125 may have a first port 150 and a second port 155, and it may (as a result of constructive interference between light reflected from a plurality of facets of the echelle grating) transmit light at a first wavelength (which may be the center wavelength of a transmission peak of the echelle grating 125) from the first port 150 of the echelle grating 125 to the second port 155 of the echelle grating 125 (or from the second port 155 to the first port 150). At a second wavelength, different from the first wavelength, the echelle grating 125 may (as a result of destructive interference between light reflected from the facets of the echelle grating) have low transmissivity, i.e., essentially all of the light entering either the first port 150 or the second port 155 of the echelle grating 125 at the second wavelength may be lost.

In operation, light at the first wavelength may exit the semiconductor optical amplifier 105, and propagate into the first port 130. A first portion of the light entering the first port 130 of the directional coupler 120 may exit the third port 140, propagate through the echelle grating, and back into the directional coupler 120 at the fourth port 145; of this light entering the fourth port 145, a portion may propagate back into the laser, and a portion may propagate out of the output 160 of the laser. Similarly, a second portion of the light entering the first port 130 of the directional coupler 120 may exit the fourth port 145, propagate through the echelle grating, and back into the directional coupler 120 at the third port 140; of this light entering the third port 140, a portion may propagate back into the laser, and a portion may propagate out of the output 160 of the laser. The proportions in which light entering one of the ports at one end of the directional coupler 120 exits respectively from the two ports at the other end of the directional coupler 120 may be determined by the coupling ratio of the directional coupler 120.

At the second wavelength, light from the semiconductor optical amplifier 105 entering the first port 130 may be transmitted in part to the first port 150 of the echelle grating 125, and lost, and in part to the second port 155 of the echelle grating 125, and lost. As such, the output reflector 115 may operate, at the first wavelength, as a partial reflector (reflecting part of the light from the semiconductor optical amplifier 105 back to the semiconductor optical amplifier 105, and transmitting part of the light from the semiconductor optical amplifier 105 to the output 160 of the laser). The reflectance, or “reflection” of the output reflector 115 may be given by 4 T t² k², and the transmittance, or “transmission” of the output reflector 115 may be given by T (t⁴+k⁴−2 t² k²) where T is the transmittance of the echelle grating 125 at the first wavelength, t is the (amplitude) transmittance of the directional coupler 120, and k is the (amplitude) coupling ratio of the directional coupler 120 (i.e., the square root of the ratio of (i) the amount of optical power coupled to the fourth port 145 to (ii) the amount of optical power received at the first port 130).

The wavelength-dependent reflectance characteristics of the output reflector 115 may cause the laser to emit light at the first wavelength, and not at other wavelengths. The linewidth of the output light, the extent to which the laser has a tendency for multimode operation, and the extent to which the laser has a tendency to hop between different modes, may be affected by the transmission of the echelle grating 125 (the terms “transmission” and “transmission function” may be used herein to mean the spectral transmittance). The calculated transmission for four different embodiments is shown, as a function of wavelength, in FIG. 1B, and the corresponding design parameters of the echelle grating 125 are shown in the table of FIG. 1C. In general, satisfactory echelle grating characteristics may be achieved with a grating order between 10 and 20, a grating waveguide aperture between 1 micron (um) and 2 microns and a Rowland circle radius between 1 mm and 2 mm. The transmission function (i.e., the transmission as a function of wavelength) may be designed to have a 3 dB bandwidth less than approximately twice the laser cavity mode spacing (which may be between 0.1 and 0.2 nm, for a cavity length of about 5 mm), to reduce the likelihood that the laser will emit light at two or more modes within the selected transmission peak of the echelle grating 125, and the echelle grating 125 may be constructed to have a free spectral range (FSR) greater than approximately half of the gain bandwidth of the semiconductor optical amplifier 105, to reduce the likelihood that the laser will emit light at the wavelength of an adjacent transmission peak of the echelle grating 125.

The waveguides and echelle grating 125 may be composed of silicon, e.g., they may be fabricated in the device layer of a silicon on insulator (SOI) wafer, and the buried oxide (BOX) insulator of the SOI wafer may form a lower cladding layer for the waveguides and for the echelle grating 125. In other embodiments, the waveguides and echelle grating 125 may be composed of silicon nitride, as discussed in further detail below.

In the embodiment of FIG. 1D, the echelle grating 125 is constructed with only a first port 150 (i.e., without a second port), and it may be referred to as a “one-port” or “reflective” wavelength-selective element, which reflects light within a narrow range of wavelengths (or, more precisely, within a plurality of transmission peaks separated from each other by the free spectra range (FSR) of the echelle grating 125). In operation, light of a certain wavelength (e.g., a first wavelength) received by the echelle grating 125 at the first port 150 is reflected (as a result of constructive interference between light reflected from the plurality of facets of the echelle grating 125) back toward the directional coupler 120. The echelle grating 125 of FIG. 1D may be referred to as a “Littrow echelle grating”. Light at other wavelengths, e.g., light at a second wavelength, may be lost, e.g., absorbed or scattered within the echelle grating 125. The embodiment of FIG. 1D has two outputs 160. A portion of the light propagating from the semiconductor optical amplifier 105 toward the echelle grating 125 is diverted to one of the outputs 160, and a portion of the light reflected by the echelle grating 125 back toward the semiconductor optical amplifier 105 is diverted to the other one of the outputs 160.

In the embodiment of FIG. 2A, the echelle grating 125 is connected in cascade with a ring (or “micro-ring”) resonator 205, so that the echelle grating 125 and the ring resonator 205 form a composite transmissive wavelength-selective element 210 having relatively high transmissivity at a first wavelength and low transmissivity at other wavelengths. The transmission function of the composite transmissive wavelength-selective element 210 is shown in FIGS. 2B and 2C (with FIG. 2C being a graph of the transmission function over a narrower range of wavelengths than FIG. 2B). In some embodiments, the laser cavity mode spacing may be (or may be within 30% of) 0.1 nm, the gain bandwidth of the RSOA may be (or may be within 30% of) 80 nm, the FSR of the echelle grating may be (or may be within 30% of) 110 nm, and the FSR of the ring resonator may be (or may be within 30% of) 0.24 nm (and the ring resonator roundtrip length may be (or may be within 30% of) 2.8 mm). The configuration of FIG. 2A may be used, for example, if the bandwidth of the echelle grating 125 is not sufficiently narrow to maintain single-mode operation of the laser. The bandwidth of the ring resonator 205 may be about 3 pm, which provides high wavelength selectivity. The other order ring resonance peaks may be suppressed by the filter profile of the echelle grating 125, as shown in FIG. 2C, which shows a side lobe suppression ratio (SMSR) of about 7 dB. The resonant wavelength of the ring resonator 205 may be actively controlled, e.g., by a tuning circuit that senses the error between the resonant wavelength of the ring resonator 205 and the desired operating wavelength of the laser, and adjusts the temperature of the ring resonator 205 (by adjusting the current of a heater thermally coupled to the ring resonator 205) to correct the resonant wavelength of the ring resonator 205.

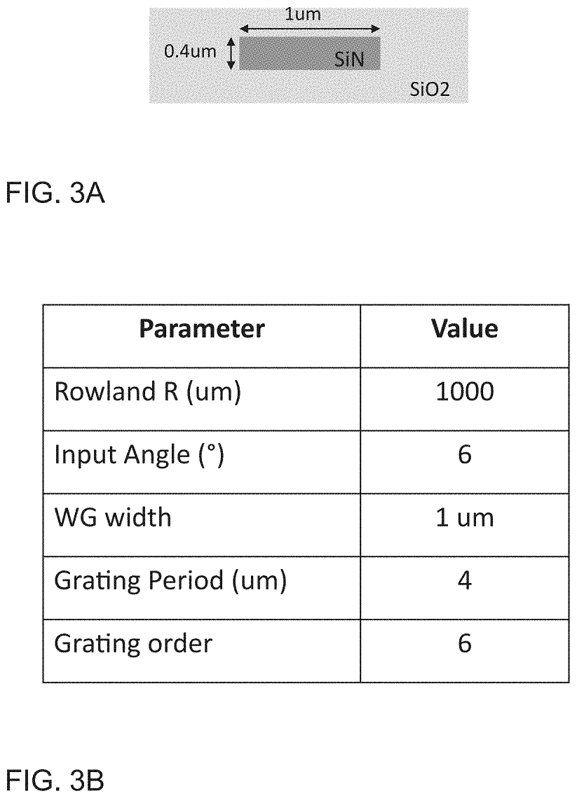

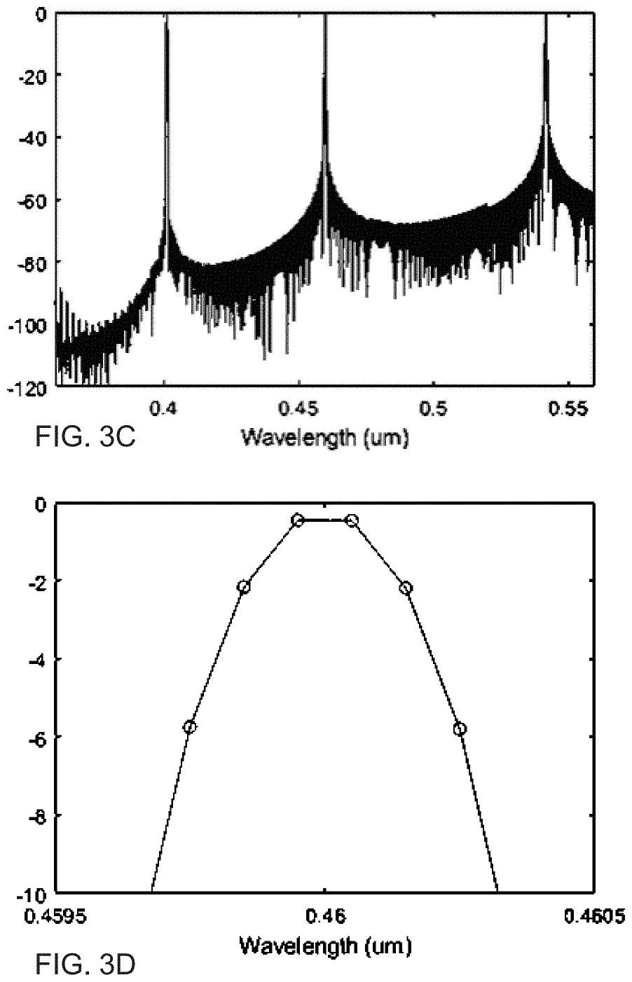

If the waveguides and the echelle grating are composed of silicon nitride (SiN), then a laser according to, e.g., FIG. 1A may be capable of emitting light having a wavelength of less than 1 micron (e.g., light having a wavelength between 400 nm and 1,000 nm), e.g., visible light. FIG. 3A shows a cross sectional view of a silicon nitride (SiN) waveguide (e.g., a SiN waveguide core), surrounded by a cladding layer of silicon dioxide, that may be used in such an embodiment. FIG. 3B shows parameters of an echelle grating 125 that may be suitable for such a laser, and FIGS. 3C and 3D show graphs, over a wide wavelength range and a narrow wavelength range respectively, of the calculated transmission function of such an echelle grating 125. Especially in the case of a visible wavelength laser, the fabrication of a DBR grating suitable for use as a wavelength-selective element may be challenging because of the small feature size such a grating would have, and in part for this reason an output reflector 115 based instead on an echelle grating may be advantageous.

In some embodiments, an arrayed waveguide grating (AWG) 405 may be used instead of the echelle grating 125, e.g., in the embodiments of FIGS. 1A, 1D, and 2A. FIGS. 4A and 4B show examples of such embodiments. The embodiment of FIG. 4A is analogous to that of FIG. 1A, and the embodiment of FIG. 4B is analogous to that of FIG. 1D. In the embodiment of FIG. 4B, the AWG 405 operates as a reflective wavelength-selective element as a result of the loop mirror 410, which operates as a broadband reflector. The embodiment of FIG. 4B has two outputs, as shown.

The parameters of the AWG 405 in the embodiments of FIGS. 4A and 4B may be selected to achieve (i) an AWG center passband wavelength aligned to the target laser wavelength (e.g., 960 nm or 660 nm), (ii) a wide free spectral range (FSR) to prevent multi-peak lasing, (iii) a narrow bandwidth (BW) to minimize cavity longitudinal mode hopping, (iv) minimum insertion loss (IL), and (v) minimum footprint. The table of FIG. 4C, for example, shows design parameters that may achieve all of these objectives to a satisfactory extent. The design parameters were selected to maintain single-mode operation while ensuring a minimum footprint.

FIGS. 4D-4F show the transmission of the AWG 405 as a function of wavelength in microns (um) for three different values of the order m of the AWG 405 (m=10, m=20 and m=30, respectively), and FIG. 4G shows the FSR and 3 dB bandwidth (3 db BW) for the same three values of the order m of the AWG 405. It may be seen from FIGS. 4D-4G that both the FSR and the 3 dB bandwidth decrease as the order m of the AWG 405 is increased. FIGS. 4H-4J show the transmission as a function of wavelength for three different values of the radius Ra of the Rowland circle of each of the star couplers of the AWG 405. The correspondence between line style and the radius of the Rowland circle is the same in all of FIGS. 4H-4J, and is shown in the legend of FIG. 4H. The table of FIG. 4K shows how the 3 dB bandwidth varies with the value of the radius Ra of the Rowland circle of each of the star couplers of the AWG 405.

FIGS. 4L and 4M show a set of waveguide ends at the transition to a free propagation region of a star coupler of an AWG 405. The cross-hatched areas shown are gaps (in the waveguide core material) separating adjacent waveguides. The waveguides may be composed of silicon or silicon nitride. For silicon nitride waveguides, the width of each waveguide at the transition to the free propagation region may be about 1.8 microns and each waveguide may be tapered, decreasing in width to a width of about 0.8 microns at some distance from the free propagation region. FIG. 4N shows the transmission T of (or, equivalently, the loss in) the tapered waveguide as a function of the length of the tapered portion.

FIG. 4O shows design parameters of an AWG designed for operation at a wavelength of 960 nm, and FIGS. 4P and 4Q show the calculated transmission function for such an AWG. Similarly, FIG. 4R shows design parameters of an AWG designed for operation at a wavelength of 660 nm, and FIGS. 4S and 4T show the calculated transmission function for such an AWG. The design parameters were selected to maintain single mode operation at target wavelength while ensuring minimum footprint. In the designs of FIGS. 4O-4T, the design parameters were adjusted so that the FSR was greater than 50 nm, the insertion loss at the transmission peak was minimized, the 3 dB bandwidth was minimized, and the side mode suppression ratio (SMSR) was greater than 25 dB.

In some embodiments the coupler is a multi-mode interference coupler or a Y-coupler instead of a directional coupler. If the coupler is a Y-coupler having a single port at the first end (facing the semiconductor optical amplifier 105) and two ports facing the wavelength-selective element, then, using the port numbering convention adopted above for the directional coupler, the coupler may have, e.g., a first port, a third port, and a fourth port, and it may lack a second port.

Some embodiments employ other combinations of the elements described above, or of other wavelength-selective elements, such as a Mach-Zehnder interferometer cascade or a Vernier ring resonator. For example, in an embodiment including a two-port wavelength-selective element (such as the embodiments of FIGS. 1A and 2A) various (simple or composite) wavelength-selective elements may be used (e.g., an AWG may be used instead of an echelle grating in the embodiment of FIG. 2A, or more than two wavelength-selective elements may be connected in cascade). Generally, a composite two-port (transmissive) wavelength-selective element may be constructed by connecting a first element selected from a set of candidate two-port wavelength-selective elements in cascade with a second element selected from the set of candidate two-port wavelength-selective elements (and optionally further connecting, in cascade, a third, fourth, or fifth element (or more)), where the set of candidate two-port wavelength-selective elements includes, for example, echelle gratings, AWGs, Mach Zehnder cascades, ring resonators, and compound ring resonators (e.g., Vernier ring resonators). Similarly, a composite one-port (or reflective) wavelength-selective element may be constructed by connecting a first element, selected from a set of candidate one-port wavelength-selective elements, in cascade with a second element, selected from the set of candidate two-port wavelength-selective elements (and optionally further connecting, in cascade, a third, fourth, or fifth element (or more)). The unconnected port of the last element of this cascade may then be connected to the coupler. The set of candidate one-port wavelength-selective elements may include (i) any cascade-connected combination of an element from the set of candidate two-port wavelength-selective elements and a reflector (e.g., a narrowband reflector such as a Littrow echelle grating or a broadband reflector such as the loop mirror of FIG. 4B), and (ii) Littrow echelle gratings. Some combinations constructed according to the principles (for constructing one-port or two-port wavelength-selective elements) disclosed above may include two of the same kind of element, with different parameters (e.g., two echelle gratings with different free spectral ranges, forming an element that may be referred to as a Vernier echelle grating pair).

Some embodiments may achieve a passive wavelength registration of 0.2 nm or less, e.g. of about 0.1 nm. As used herein, “passive wavelength registration” refers to the extent to which the laser's output wavelength is repeatable without the use of active tuning (e.g., without the use of active temperature control to keep the operating wavelength at or near a target operating wavelength) or to the extent to which the laser's output wavelength is near a desired output wavelength, which may be specified, e.g., by an industry-adopted standard. For example, if 100 operating lasers are fabricated in order, it may be that the 100 respective operating wavelengths have a sample standard deviation of between 0 nm and 2 nm, e.g., they may have a sample standard deviation of 0.1 nm. As used herein, an “operating” laser is one that meets performance requirements (e.g., requirements on output power, power stability, single-mode operation, or wavelength stability) other than wavelength accuracy, and, as such, the act of fabricating 100 operating lasers, in order, may also include fabricating (and rejecting) a number of non-operating lasers.

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X−Y and the second quantity is at most X+Y. As used herein, when a second number is “within Y %” of a first number, it means that the second number is at least (1−Y/100) times the first number and the second number is at most (1+Y/100) times the first number. As used herein, the word “or” is inclusive, so that, for example, “A or B” means any one of (i) A, (ii) B, and (iii) A and B.

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed herein could be termed a second element, component, region, layer or section, without departing from the spirit and scope of the inventive concept.

Any parameter value disclosed herein need not, in all embodiments, have precisely the disclosed value, but may, in some embodiments, be within 45% of the disclosed value.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1+35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

It will be understood that when an element is referred to as being “directly connected” or “directly coupled” to another element, there are no intervening elements present. As used herein, “generally connected” means connected by an optical or electrical path that may contain arbitrary intervening elements, including intervening elements the presence of which qualitatively changes the behavior of the optical device or circuit. As used herein, “connected” means (i) “directly connected” or (ii) connected with intervening elements, the intervening elements being ones (e.g., short sections of waveguide) that do not qualitatively affect the behavior of the circuit.

As used herein, a first element and a second element are connected in “cascade” when a port of the first element is connected (e.g., by a waveguide) to a port of the second element, so that light may propagate from the first element into the second element (or from the second element into the first element).

Although exemplary embodiments of a laser with wavelength-selective reflector have been specifically described and illustrated herein, many modifications and variations will be apparent to those skilled in the art. Accordingly, it is to be understood that a laser with wavelength-selective reflector constructed according to principles of this disclosure may be embodied other than as specifically described herein. The invention is also defined in the following claims, and equivalents thereof.

What is claimed is:

1. A laser, comprising:
an optical amplifier; and
an output reflector,
the output reflector being configured to receive light from the optical amplifier and to reflect light at a first wavelength back toward the optical amplifier,
the output reflector comprising:
a wavelength-selective element, and
a coupler configured to receive the light from the optical amplifier and to couple a portion of the light to the wavelength-selective element.

2. The laser of claim 1, wherein the wavelength-selective element comprises an arrayed waveguide grating.

3. The laser of claim 1, wherein the arrayed waveguide grating has a free spectral range greater than 50 nm.

4. The laser of claim 1, wherein the wavelength-selective element comprises an echelle grating.

5. The laser of claim 4, wherein the echelle grating occupies less than 4 mm².

6. The laser of claim 4, wherein the echelle grating has a 3 dB bandwidth of less than 0.6 nm.

7. The laser of claim 1, wherein:
the wavelength-selective element has a first port,
the optical amplifier is connected to a first port of the coupler, the first port of the coupler being at a first end of the coupler,
a third port of the coupler is connected to the first port of the wavelength-selective element, the third port of the coupler being at a second end of the coupler.

8. The laser of claim 4, wherein the wavelength-selective element is a Littrow echelle grating.

9. The laser of claim 1, wherein the wavelength-selective element further has a second port.

10. The laser of claim 1, wherein the second port of the wavelength-selective element is connected to a fourth port of the coupler, the fourth port of the coupler being at the second end of the coupler.

11. The laser of claim 1, wherein the wavelength-selective element is a composite wavelength-selective element comprising:
a first wavelength-selective element, and
a second wavelength-selective element.

12. The laser of claim 11, wherein the first wavelength-selective element is an arrayed waveguide grating.

13. The laser of claim 11, wherein the first wavelength-selective element is an echelle grating.

14. The laser of claim 11, wherein the second wavelength-selective element is a ring resonator.

15. The laser of claim 14, further comprising a tuning circuit configured to control a resonant wavelength of the ring resonator.

16. The laser of claim 1, wherein the coupler comprises a directional coupler.

17. The laser of claim 1, wherein the coupler comprises a Y-coupler.

18. The laser of claim 1, wherein the coupler is connected to the wavelength-selective element by a waveguide having a core comprising at least 70 atomic percent silicon.

19. The laser of claim 1, wherein the coupler is connected to the wavelength-selective element by a waveguide having a core comprising at least 35 atomic percent silicon and at least 35 atomic percent nitrogen.

20. The laser of claim 19, wherein the laser is capable of operating at a wavelength of less than 1 micron.

21. The laser of claim 1, configured to produce light at a first wavelength, the first wavelength being within 0.2 nm of a standard-specified wavelength.
